(19) United States
(12) Patent Application Publication
(10) Pub. No.: US 2008/0048332 A1
(43) Pub. Date: Feb. 28, 2008

(54) METHOD FOR FORMING INTERMETAL DIELECTRIC IN SEMICONDUCTOR DEVICE

(76) Inventor: Kyung-Min Park, Luncheon (KR)

Correspondence Address: SHERR & NOURSE, PLLC, 620 HERNDON PARKWAY, SUITE 200, HERNDON, VA, 20170, US

(21) Appl. No.: 11/841,038

(22) Filed: Aug. 20, 2007

(30) Foreign Application Priority Data
Aug. 22, 2006 (KR) 10-2006-79328

(51) Int. Cl. H01L 23/52; H01L 21/4763

(52) U.S. Cl. 257/773; 438/622; 257/E21.495; 257/E23.141

(57) ABSTRACT

A method for forming an intermetal dielectric in a semiconductor device includes the steps of: forming metal wiring patterns electrically connecting circuit devices on a silicon substrate provided with the predetermined semiconductor circuit devices; forming a first silicon oxide film electrically isolating the metal wiring patterns; forming a second silicon oxide film on the first silicon oxide film; and ion-implanting silicon or oxygen into the inside of the second silicon oxide film.

The present application claims priority under 35 U.S.C. 119 to Korean Patent Application 10-2006-79328, filed on Aug. 22, 2006, which is hereby incorporated by reference in its entirety.

### BACKGROUND

Generally, a semiconductor device manufacturing process is divided into a front end of the line (FEOL) forming a transistor on a silicon substrate and a back end of the line (BEOL) forming a wiring. Wherein the term “wiring” encompasses implementing a power supply and a path of a signal transfer on the silicon by forming a circuit through the connection of individual transistors to each other in a semiconductor integrated circuit.

The metal wiring formed to electrically connect a plurality of circuit devices of a semiconductor device is usually formed in multiple layers, wherein the respective metal wiring layers are isolated from each other, for example, using silicon oxide or other dielectric. Also, the metal wirings of the respective layers are formed in a pattern having various shapes, and silicon oxide containing fluorine F such as a fluorinated silicate glass (FSG; FxSiOy) is generally used as an intermetal dielectric in order to reduce parasitic capacitance generated between the metal wiring patterns. The FSG oxide film buried between the metal wiring patterns is commonly made by means of a chemical vapor deposition (CVD) process, wherein the CVD process additionally adds SiF₄ when forming a SiO₂ thin film by implanting silane SiH₄ and oxygen. In particular, if too much fluorine F is added, it can cause a problem where the metal wires may erode due to the fluorine escaping from the thin film in a reactive ion etching of the thin film layer. Therefore, the amount of fluorine is preferably about 6% at maximum. The more fluorine F there is, the lower the dielectric constant becomes so that the parasitic capacitance between the metal wiring patterns is advantageously reduced; however, the added amount of fluorine is restricted due to the erosion problem mentioned above.

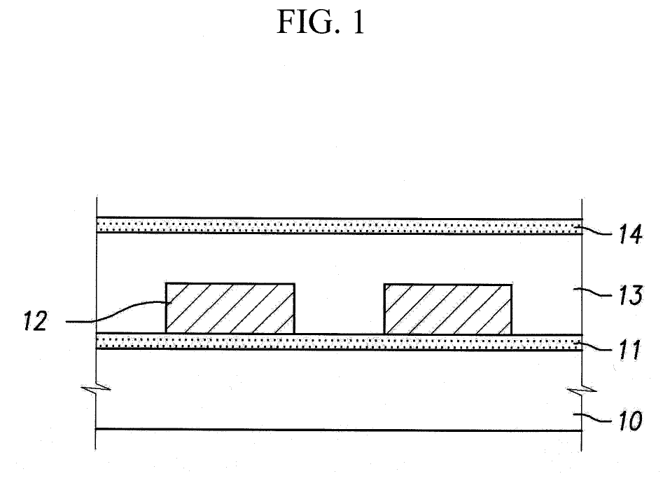

Example FIG. 1 shows one example of a multi-layer metal wiring structure using FSG. As shown in example FIG. 1, an undoped silicate glass (USG) 11 oxide film is formed on a silicon semiconductor substrate 10 provided with a predetermined structure (for example, a circuit device such as a transistor, etc., or a lower metal wiring). The USG oxide film 11 is the oxide film that is typically not doped with fluorine and is provided to prevent the diffusion of fluorine from a FSG oxide film 13 (formed in a subsequent process) to another layer. Thereafter, predetermined metal wiring patterns 12 are formed on the USG oxide film 11. The metal wiring patterns 12 may be formed by first forming a metal layer on the USG oxide film 11 and then patterning the metal layer using the USG oxide film 11 as an etch stop layer. Then, the FSG oxide film 13 is formed between the metal wiring patterns 12 formed as above, wherein its surface is planarized by means of a chemical mechanical polishing process or an etch-back process. Thereafter, an another USG film 14 is formed on the FSG oxide film 13. In such a manner, the metal wiring layers of the desired number of layers can be formed.

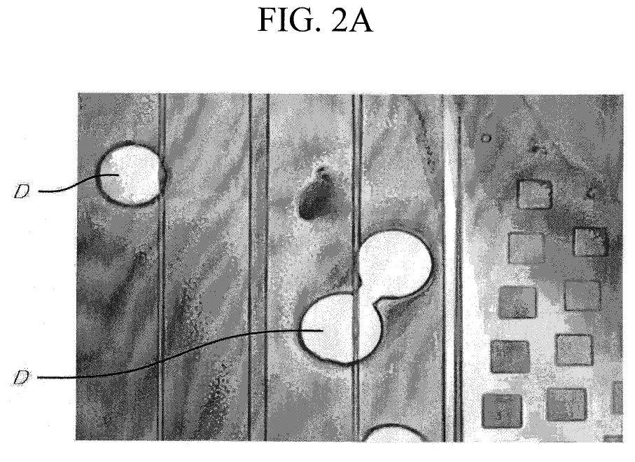

In a semiconductor device including the multi-layer metal wiring as described above, in particular, a CMOS image sensor, when oxide films of different materials are stacked, interface stress can result between the oxide films of different materials. Furthermore, a portion of the oxide film may be detached due to the interface stress between the oxide films and a circular defect can be formed inside the oxide film. Such a circular defect may cause unexpected performance deterioration, and in particular, when the circular defect occurs in the USG oxide film, it cannot properly perform its function as a diffusion stop layer against the fluorine. Example FIGS. 2a and 2b show an optical image and a scanning electron microscope image displaying states where a circular defect D occurs on the surface and inside of the oxide film. If the circular defect occurs inside the oxide film as described above, it affects the subsequent process, and can cause a deterioration in both the yield and performance of the semiconductor device.

### SUMMARY

Embodiments relate to a method for forming a portion of a semiconductor device. In accordance with this method a first and second metal wiring patterns are formed; a first silicon oxide film is formed electrically isolating the first and second metal wiring patterns, and a second silicon oxide film is formed on the first silicon oxide film. Also ions of an element are implanted into the second silicon oxide film, wherein the element is one of oxygen or silicon.

Embodiments relate to a portion of a semiconductor device that includes first and second metal wiring patterns; a first silicon oxide film electrically isolating the first and second metal wiring patterns; and a second silicon oxide film on the first silicon oxide film; wherein the second silicon oxide film includes ions implanted from an element, wherein the element is one of oxygen or silicon.

Embodiments relate to a method for reducing interface stress between layers of different materials. In accordance with this method, the following steps are performed: forming a first silicon oxide film; forming a second silicon oxide film on the first silicon oxide film; and ion-implanting ions from an element into the second silicon oxide film, wherein the element is one of silicon or oxygen.

### DRAWINGS

Example FIG. 1 is a cross-sectional view of a multi-layer metal wiring structure of the related art using a FSG.

Example FIG. 2a shows an optical image displaying a state where a circular defect D occurs on the surface of an oxide film, and FIG. 2b shows a scanning electron microscope image displaying a state where a circular defect D occurs inside an oxide film.

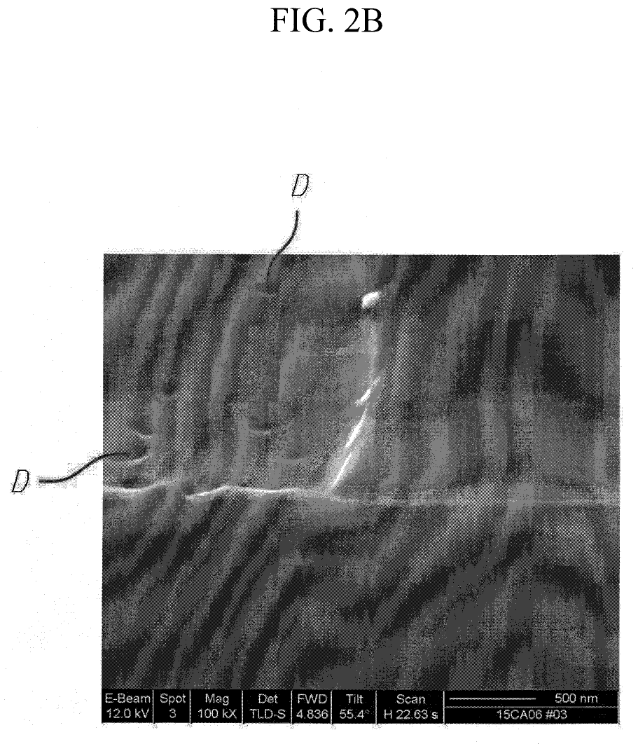

Example FIG. 3 is a cross-sectional view of a device explaining a method for forming an intermetal dielectric in a semiconductor device according embodiments.

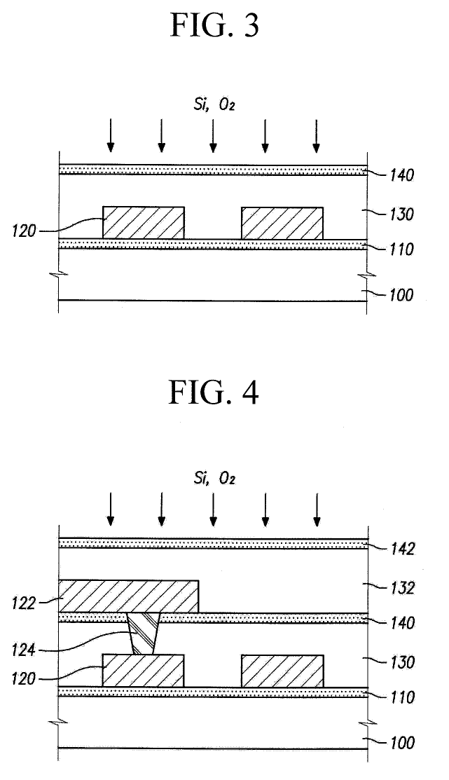

Example FIG. 4 is a cross-sectional view of a device explaining a method for forming an intermetal dielectric in a semiconductor device in the case where a two-layer metal wiring is formed.

### DESCRIPTION

Hereinafter, a method for forming an intermetal dielectric in a semiconductor device according to embodiments will be described in detail with reference to the accompanying drawings.

First, as shown in example FIG. 3, an undoped silicate glass (USG) 110 oxide film is formed on a silicon semiconductor substrate 100 provided with a predetermined structure (for example, a circuit device such as a transistor or a lower metal wiring). The USG oxide film 110 is the oxide film that is not doped with fluorine and is used to prevent the diffusion of fluorine from a FSG oxide film 130 (formed in a subsequent process) to another layer.

Thereafter, predetermined metal wiring patterns 120 are formed on the USG oxide film 110. The metal wiring patterns 120 may be formed by first forming a metal film on the USG oxide film 110 and then patterning the metal layer using the USG oxide film 110 as an etch stop layer. The FSG oxide film 130 is formed between the metal wiring patterns 120 formed as above, wherein its surface may then be planarized by means of a chemical mechanical polishing process or an etch-back process.

In the case of using copper (Cu) as a material of the metal wiring, it is preferable to use a separate process, that is, a damascene process, instead of the patterning manner of the metal film described above. In the case of the damascene process, the FSG oxide film 130 is first formed on the USG oxide film 110, then a damascene structure (e.g., a via and/or a trench) is included in the inside of the FSG oxide film 130, and copper is buried in the damascene structure. The surface of the FSG oxide film 130 may then be planarized by means of the CMP process.

Next, a USG oxide film 140 may be back formed on the metal wiring 120 and the planarized FSG oxide 130. At this time, interface stress can be generated between the FSG oxide film 130 and the USG oxide film 140 due to the difference in their materials. For example, if the oxide films of different materials are formed, the interface stress can be accentuated in a subsequent annealing process due to the difference in thermal expansion coefficient. Accordingly, in order to reduce the interface stress between the FSG oxide film 130 and the USG oxide film 140, the inside of the USG oxide film 140 is ion-implanted with silicon and/or oxygen. As such, if the inside of the USG oxide film is ion-implanted with silicon or oxygen, the stress generated at the interface between the USG oxide film 140 and the FSG oxide film 130 can be relieved. In particular, the thermal stress due to the difference in the thermal expansion coefficient in the subsequent process can be considerably reduced. The process conditions for the ion implantation process of silicon or oxygen, for example, ion implantation amount, ion implantation energy, and the like can be selected based on considerations such as the thickness of the USG oxide film and the thickness of the FSG oxide film. These conditions can easily be appreciated by those skilled in this area.

As shown in example FIG. 4, the metal wiring process is back performed on the USG oxide film 140 to form an upper metal wiring 122 and an upper FSG intermetal dielectric 132. At this time, a contact plug 124 can be formed in order to electrically connect the upper metal wiring 122 and the lower metal wiring 120. After an USG oxide film 142 is back formed on the upper FSG intermetal dielectric 132, the ion implantation process of silicon or oxygen is performed as above, making it possible to relieve the interface stress between the FSG oxide film 132 and the USG oxide film 142.

According to embodiments, when forming an intermetal dielectric for electrically isolating the metal wirings of the respective layers in a multi-layer metal wiring process, the interface stress between the oxide films of different materials can be relieved or reduced by means of an ion implantation process of silicon or oxygen. Additionally, the adhesion of the respective oxide films can be improved at the same time. As a result, a circular defect generated due to the interface stress between the oxide films can be prevented, thereby improving both the yield and performance of the device.

It will be apparent to those skilled in the art that various modifications and variations can be made without departing from the spirit or scope of the embodiments described herein. Thus, it is intended that modifications and variations of the embodiments also be covered that come within the scope of the appended claims and their equivalents.

What is claimed is:

1. A method for forming a portion of a semiconductor device comprising:
forming a first and second metal wiring patterns;
forming a first silicon oxide film electrically isolating the first and second metal wiring patterns;
forming a second silicon oxide film on the first silicon oxide film; and
ion-implanting ions of an element into the second silicon oxide film, the element selected from one of oxygen and silicon.

2. The method of claim 1, wherein the first and second metal patterns electrically connect circuit devices on a silicon substrate of the semiconductor device.

3. The method of claim 1, wherein the first silicon oxide film comprises a FSG oxide film.

4. The method of claim 1, wherein the second silicon oxide film comprises a USG oxide film.

5. The method of claim 1, wherein the semiconductor device comprises a CMOS image sensor.

6. The method of claim 1, further comprising:
forming a third silicon oxide film on a silicon substrate of the semiconductor device, wherein the first metal pattern and the first silicon oxide film are formed on an upper portion of the third silicon oxide film.

7. The method of claim 6, wherein the third silicon oxide film comprises a USG oxide film.

8. The method of claim 1, wherein the first and second silicon dioxide films form an intermetal dielectric in the semiconductor device.

9. A portion of a semiconductor device comprising:
first and second metal wiring patterns;
a first silicon oxide film electrically isolating the first and second metal wiring patterns; and
a second silicon oxide film on the first silicon oxide film; wherein the second silicon oxide film includes implanted ions of an element, the element selected from one of oxygen and silicon.

10. The portion of a semiconductor device of claim 9, wherein the first and second metal patterns electrically connect circuit devices on a silicon substrate of the semiconductor device.

11. The portion of a semiconductor device of claim 9, wherein the first silicon oxide film comprises a FSG oxide film.

12. The portion of a semiconductor device of claim 9, wherein the second silicon oxide film comprises a USG oxide film.

13. The portion of a semiconductor device of claim 9, wherein the semiconductor device comprises a CMOS image sensor.

14. The portion of a semiconductor device of claim 9, further comprising:
a third silicon oxide film on a silicon substrate of the semiconductor device, wherein the first metal pattern and the first silicon oxide film are formed on an upper portion of the third silicon oxide film

15. The portion of a semiconductor device of claim 14, wherein the third silicon oxide film comprises a USG oxide film.

16. The portion of a semiconductor device of claim 9, wherein the first and second silicon dioxide films form an intermetal dielectric in the semiconductor device.

17. A method for reducing interface stress between layers of different materials comprising:
forming a first silicon oxide film;
forming a second silicon oxide film on the first silicon oxide film; and
ion-implanting ions of an element into the second silicon oxide film, the element selected from one of oxygen and silicon.

18. The method of claim 17, wherein the first silicon oxide film comprises a FSG oxide film.

19. The method of claim 17, wherein the second silicon oxide film comprises a USG oxide film.

20. The method of claim 17, wherein the first and second silicon dioxide films form an intermetal dielectric isolating a first and a second metal wiring pattern.
